(19) United States
(12) Patent Application Publication
(10) Pub. No.: US 2020/0294775 A1
(43) Pub. Date: Sep. 17, 2020

(54) PLASMA PROCESSING APPARATUS

(71) Applicant: TOKYO ELECTRON LIMITED, Tokyo (JP)

(72) Inventor: Satoru KAWAKAMI, Nirasaki City (JP)

(21) Appl. No.: 16/815,691

(22) Filed: Mar. 11, 2020

(30) Foreign Application Priority Data
Mar. 13, 2019 (JP) 2019-046237

(51) Int. Cl. H01J 37/32; H05H 1/46

(52) U.S. Cl. CPC H01J 37/32669; H05H 1/46; H01J 37/32357

(57) ABSTRACT

A plasma processing apparatus includes a gas supply configured to supply a gas into a plasma generation chamber; a first power supply configured to convert the gas supplied into the plasma generation chamber into plasma by supplying a first high-frequency power into the plasma generation chamber; a separation plate configured to separate the plasma generation chamber and a processing chamber below the plasma generation chamber, the separation plate having a plurality of through holes so as to guide active species contained in the plasma generated in the plasma generation chamber to the processing chamber; and a temperature controller having a flow path through which a fluid flows in a temperature-controlled manner, the temperature controller being configured to control a temperature of the separation plate through heat exchange with the fluid.

### CROSS-REFERENCE TO RELATED APPLICATION

This application is based upon and claims the benefit of priority from Japanese Patent Application No. 2019-046237, filed on Mar. 13, 2019, the entire contents of which are incorporated herein by reference.

### TECHNICAL FIELD

Various aspects and embodiments of the present disclosure relate to a plasma processing apparatus.

### BACKGROUND

In a film formation process using plasma, a plasma generation space in which plasma is generated and a processing space in which a workpiece is processed may be separated for the purpose of reducing ion damage to the workpiece and improving step coverage. The plasma generation space and the processing space are separated using, for example, a plate having a plurality of through holes. Therefore, the ions contained in the plasma generated in the plasma generation space are hindered from infiltrating into the processing space by the plate, and thus damage to the workpiece by the ions is reduced. In addition, since the active species contained in the plasma are supplied to the workpiece through the holes in the plate, it is possible to perform film formation mainly using the active species, and thus improve step coverage.

### PRIOR ART DOCUMENT

### Patent Document

Japanese Laid-Open Patent Publication No. H11-168094

### SUMMARY

According to embodiments of the present disclosure, there is provided a plasma processing apparatus including a gas supply configured to supply a gas into a plasma generation chamber; a first power supply configured to convert the gas supplied into the plasma generation chamber into plasma by supplying a first high-frequency power into the plasma generation chamber; a separation plate configured to separate the plasma generation chamber and a processing chamber below the plasma generation chamber, the separation plate having a plurality of through holes so as to guide active species contained in the plasma generated in the plasma generation chamber to the processing chamber; and a temperature controller having a flow path through which a fluid flows in a temperature-controlled manner, the temperature controller being configured to control a temperature of the separation plate through heat exchange with the fluid.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view illustrating an exemplary plasma processing apparatus in a first embodiment of the present disclosure.

FIG. 2 is a plan view illustrating an exemplary cooling plate in a first embodiment of the present disclosure.

FIG. 3 is a cross-sectional view illustrating the exemplary cooling plate in the first embodiment of the present disclosure, taken along line A-A.

FIG. 4 is a cross-sectional view illustrating the exemplary cooling plate in the first embodiment of the present disclosure, taken along line B-B.

FIG. 5 is a cross-sectional view illustrating an exemplary cooling plate in a second embodiment of the present disclosure, taken along line A-A.

FIG. 6 is a cross-sectional view illustrating the exemplary cooling plate in the embodiment of the present disclosure, taken along line B-B.

FIG. 7 is a cross-sectional view illustrating an exemplary cooling plate in a third embodiment of the present disclosure.

FIG. 8 is a plan view illustrating an exemplary cooling plate in a fourth embodiment of the present disclosure.

FIG. 9 is a cross-sectional view illustrating the exemplary cooling plate in the fourth embodiment of the present disclosure, taken along line A1-A1.

FIG. 10 is a cross-sectional view illustrating the exemplary cooling plate in the fourth embodiment of the present disclosure, taken along line A2-A2.

FIG. 11 is a cross-sectional view illustrating the exemplary cooling plate in the fourth embodiment of the present disclosure, taken along line B-B.

FIG. 12 is a cross-sectional view illustrating an exemplary cooling plate in a fifth embodiment of the present disclosure.

FIG. 13 is a schematic cross-sectional view illustrating an exemplary cooling plate in a sixth embodiment of the present disclosure.

FIG. 14 is a schematic cross-sectional view illustrating an exemplary cooling plate in a seventh embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

A separation plate, which separates a plasma generation space and a processing space is heated by the plasma generated in the plasma generation space. When the separation plate is excessively heated, the separation plate may be deformed or broken by the stress generated by a thermal gradient. Therefore, it is necessary to suppress the temperature rise of the separation plate.

Therefore, the present disclosure provides a technology capable of suppressing a rise in the temperature of the separation plate.

### First Embodiment

### [Configuration of Plasma Processing Apparatus 1]

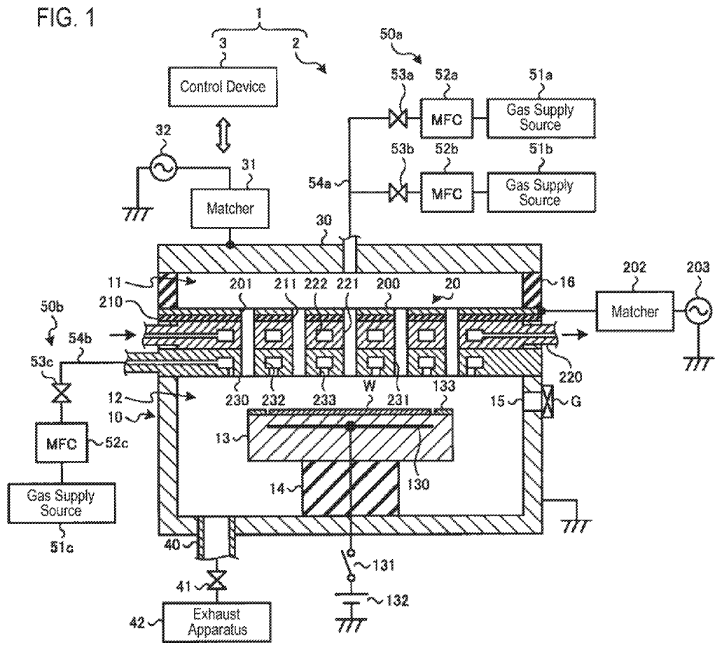

FIG. 1 is a schematic cross-sectional view illustrating an exemplary plasma processing apparatus 1 in a first embodiment of the present disclosure. The plasma processing apparatus 1 is, for example, a parallel-plate capacitively coupled plasma atomic layer deposition (ALD) apparatus. The plasma processing apparatus 1 includes an apparatus body 2 and a control device 3. The apparatus body 2 includes a processing container 10 formed of, for example, aluminum having an anodized surface, and having a substantially cylindrical space formed therein. The processing container 10 may be formed of pure aluminum or aluminum sprayed with ceramics or the like. The processing container 10 is grounded.

A stage 13 on which a wafer W is placed is provided in the processing container 10. The stage 13 is formed of, for example, ceramics, aluminum, or a combination thereof, and is supported by a support member 14. An electrode 130 is provided in the stage 13. A DC power supply 132 is connected to the electrode 130 via a switch 131. The wafer W is placed on the upper surface of the stage 13, and is attracted and held on the upper surface of the stage 13 by an electrostatic force generated on the surface of the stage 13 by a DC voltage supplied from the DC power supply 132 to the electrode 130 via the switch 131. Within the stage 13, a temperature control mechanism including a heater (not illustrated) and a flow path through which a coolant flows, is provided.

An edge ring 133 formed of, for example, ceramics is provided on the upper surface of the stage 13. The edge ring 133 is sometimes called a focus ring. The edge ring 133 improves the uniformity of plasma processing on the surface of the wafer W. Instead of the edge ring 133, the upper surface portion of the stage 13 on which the wafer W is placed may have a pocket shape engraved along the shape of the wafer W.

An opening 15 is provided in the side wall of the processing container 10, and the opening 15 is opened/closed by a gate valve G. An exhaust port 40 is provided in the bottom portion of the processing container 10. An exhaust device 42 is connected to the exhaust port 40 via a pressure adjustment valve 41. By driving the exhaust device 42, the gas in the processing container 10 is exhausted through the exhaust port 40, and by adjusting the degree of opening of the pressure adjustment valve 41, the pressure in the processing container 10 is adjusted.

A substantially disk-shaped electrode 30 is provided above the stage 13. The electrode 30 is supported on the upper portion of the processing container 10 via an insulating member 16 such as ceramics. The electrode 30 is formed of a conductive metal such as aluminum (Al) or nickel (Ni).

A gas supply pipe 54a is connected to the electrode 30, and the gas supplied through the gas supply pipe 54a diffuses in the plasma generation chamber 11 below the electrode 30. A gas supply 50a is connected to the gas supply pipe 54a. The gas supply 50a includes gas supply sources 51a to 51b, mass flow controllers (MFCs) 52a to 52b, and valves 53a to 53b. The gas supply 50a is an example of a gas supply part.

The gas supply source 51a, which is a supply source of a purge gas, is connected to the valve 53a via the MFC 52a. In the present embodiment, the purge gas is, for example, an inert gas such as He gas, Ar gas, or N₂ gas. The MFC 52a controls the flow rate of the purge gas supplied from the gas supply source 51a, and supplies the purge gas, of which the flow rate is controlled, into the plasma generation chamber 11 through the valve 53a and the gas supply pipe 54a.

The gas supply source 51b, which is a supply source of a reaction gas, is connected to the valve 53b via the MFC 52b. In the present embodiment, the reaction gas is, for example, O₂ gas, H₂O gas, NH₃ gas, N₂ gas. H₂ gas, or the like. The MFC 52b controls the flow rate of the reaction gas supplied from the gas supply source 51b, and supplies the reaction gas, of which the flow rate is controlled, into the plasma generation chamber 11 through the valve 53b and the gas supply pipe 54a. The gas is supplied into the plasma generation chamber 11 in the form of a shower.

A high-frequency power supply 32 is electrically connected to the upper electrode 30 via a matcher 31. The high-frequency power supply 32 supplies a first high-frequency power for generating plasma, for example, a first high-frequency power having a frequency of 300 kHz to 2.45 GHz to the electrode 30 via the matcher 31. The high-frequency power supply 32 is an example of a first power supply. The matcher 31 matches the internal impedance of the high-frequency power supply 32 with a load impedance. The first high-frequency power supplied to the electrode 30 is radiated from the lower surface of the electrode 30 into the plasma generation chamber 11. The reaction gas supplied into the plasma generation chamber 11 is converted into plasma by the first high-frequency power radiated into the plasma generation chamber 11.

Between the electrode 30 and the stage 13, there is provided a separation unit 20 configured to separate the space within the processing container 10 into a plasma generation chamber 11 and a processing chamber 12. The separation unit 20 has a separation plate (e.g. an electrode plate 200), an insulating plate 210, a temperature controller (e.g. a cooling plate 220), and a gas supply plate 230.

The electrode plate 200 is formed of, for example, a metal such as aluminum having an anodized surface. The electrode plate 200 is provided with a plurality of through holes 201 penetrating the electrode plate 200 in the thickness direction. The electrode plate 200 is supported by the insulating member 16 and the insulating plate 210 so as to be parallel to the electrode 30. The electrode plate 200 is an example of a separation plate.

A high-frequency power supply 203 is electrically connected to the upper electrode plate 200 via a matcher 202. The high-frequency power supply 203 is a second high-frequency power for controlling the distribution of plasma in the plasma generation chamber 11, the density of plasma in the plasma generation chamber 11, the amount of active species passing through the through holes 201 in the electrode plate 200, and the like. The high-frequency power supply 203 supplies the second high-frequency power having a frequency different from that of the first high-frequency power to the electrode plate 200 via the matcher 202. The frequency of the second high-frequency power is, for example, 300 kHz to 300 MHz. The high-frequency power supply 203 is an example of a second power supply. The matcher 202 matches the internal impedance of the high-frequency power supply 203 with a load impedance.

The insulating plate 210 is formed of, for example, an insulator such as ceramics or quartz, and is provided between the electrode plate 200 and the cooling plate 220. The insulating plate 210 is provided with a plurality of through holes 211 which penetrates the insulating plate 210 in the thickness direction. The electrode plate 200 and the cooling plate 220 are electrically insulated by the insulating plate 210.

The cooling plate 220 is formed of a metal such as aluminum having an anodized surface. The cooling plate 220 is provided with a plurality of through holes 221 that penetrates the cooling plate 220 in the thickness direction. The cooling plate 220 is supported by the side wall of the processing container 10 so as to be parallel to the electrode 30. The cooling plate 220 is in contact with the surface of the electrode plate 200 near the processing chamber 12 via the insulating plate 210. The cooling plate 220 is grounded via the side wall of the processing container 10.

The gas supply plate 230 is formed of a metal such as aluminum having an anodized surface. The gas supply plate 230 is provided with a plurality of through holes 231 that penetrates the gas supply plate 230 in the thickness direction. The gas supply plate 230 is disposed in the processing chamber 12, and is supported by the side wall of the processing container 10. The gas supply plate 230 is grounded via the side wall of the processing container 10.

A flow path 232 is formed in the gas supply plate 230, and gas ejection ports 233 are provided in the flow path 232. A gas supply 50b is connected to the flow path 232. The gas supply 50b includes a gas supply source 51c, an MFC 52c, and a valve 53c. A gas supply source 51c, which is a supply source of a precursor gas, is connected to the valve 53c via the MFC 52c.

In the present embodiment, the precursor gas is, for example, bis(diethylamino)silane (H₂Si[N(C₂H₅)₂]₂) gas, dichlorosilane (SiH₂Cl₂) gas, or the like. The MFC 52c controls the flow rate of the precursor gas supplied from the gas supply source 51c, and supplies the precursor gas, of which the flow rate is controlled, into the flow path 232 in the gas supply plate 230 through the valve 53c. The precursor gas supplied into the flow path 232 diffuses in the flow path 232 and is supplied from the gas ejection ports 233 into the processing chamber 12 in a shower shape. The space in the plasma generation chamber 11 and the space in the processing chamber 12 are connected to each other through the through holes in the separation unit 20, that is, the through holes 201 in the electrode plate 200, the through holes 211 in the insulating plate 210, the through holes 221 in the cooling plate 220, and the through holes 231 in the gas supply plate 230.

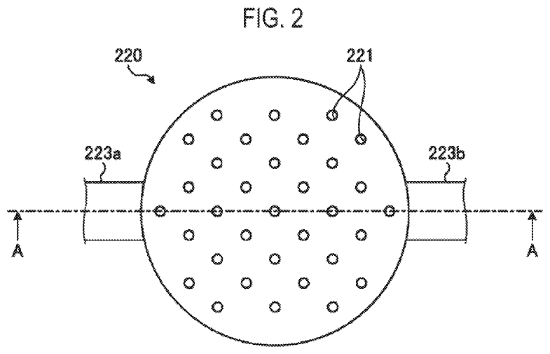

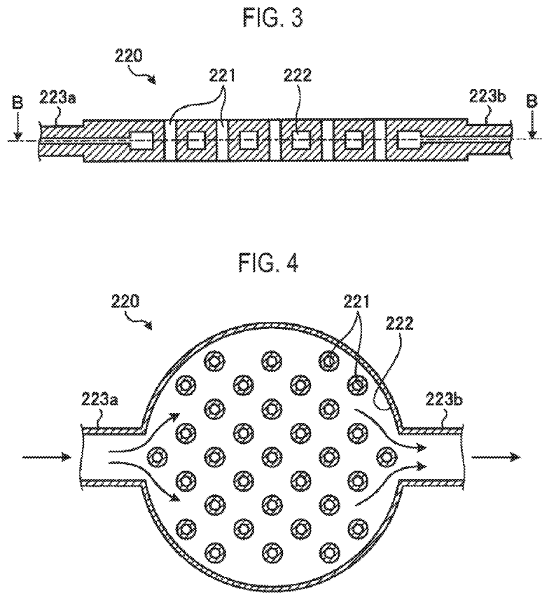

Descriptions will be continued with reference to FIGS. 2 to 4. FIG. 2 is a plan view illustrating an exemplary cooling plate 220 in a first embodiment of the present disclosure, and FIG. 3 is a cross-sectional view illustrating the exemplary cooling plate 220 in the first embodiment of the present disclosure, taken along line A-A. FIG. 4 is a cross-sectional view illustrating the exemplary cooling plate 220 in the first embodiment of the present disclosure, taken along line B-B. The A-A cross section of the cooling plate 220 exemplified in FIG. 2 corresponds to FIG. 3, and the B-B cross section of the cooling plate 220 exemplified in FIG. 3 corresponds to FIG. 4. The number of through holes 221 provided in the cooling plate 220 exemplified in FIGS. 1 to 4 is smaller than the actual number for convenience of description.

In the cooling plate 220, a flow path 222 through which a temperature-controlled fluid circulates is formed. The fluid flowing in the flow path 222 is supplied from a temperature control device such as a chiller (not illustrated) through a pipe 223a. Then, for example, the fluid flowing in the flow path 222 as indicated by the arrows in FIG. 4 is returned to the temperature control device through the pipe 223b. The fluid flowing in the flow path 222 is, for example, a liquid such as Galden (registered trademark). The fluid flowing in the flow path 222 may be another liquid such as water, or a gas.

The electrode plate 200 is heated by the plasma generated in the plasma generation chamber 11, and the heat of the electrode plate 200 is transferred to the cooling plate 220 via the insulating plate 210. The heat of the cooling plate 220 is transferred to the fluid by heat exchange with the fluid flowing in the flow path 222. By controlling the temperature of the fluid flowing in the flow path 222, it is possible to cool the electrode plate 200, the insulating plate 210, and the cooling plate 220. This suppresses the temperature rise of the separation unit 20, and thus suppresses deformation and breakage of the separation unit 20. The cooling plate 220 is an example of a temperature controller.

Returning to FIG. 1, descriptions will be continued. The control device 3 has a memory, a processor, and an input/output interface. The processor controls the respective parts of the apparatus body 2 via an input/output interface by reading and executing a program or a recipe stored in the memory. In the present embodiment, the control device 3 controls each part of the apparatus body 2 such that a silicon oxide film or the like is formed on the wafer W placed on the stage 13 through, for example, plasma-enhanced ALD (PEALD) method.

For example, the gate valve G is opened, and a wafer W is carried into the processing container 10 by a transport mechanism, such as a robot arm (not shown), and is placed on the stage 13. Then, after the gate valve G is closed, the control device 3 drives the exhaust device 42 and adjusts the opening degree of the pressure adjustment valve 41 so as to adjust the pressure in the processing container 10. Then, the control device 3 executes a plurality of ALD cycles including an adsorption step, a first purge step, a reaction step, and a second purge step, thereby forming a predetermined film on the wafer W placed on the stage 13.

In the adsorption step, the valve 53c is opened, and the precursor gas, of which the flow rate is controlled by the MFC 52c, is supplied into the flow path 232 in the gas supply plate 230 through the gas supply pipe 54b. The precursor gas supplied into the flow path 232 diffuses in the flow path 232 and is supplied from the gas ejection ports 233 into the plasma generation chamber 11 in a shower shape. The molecules of the precursor gas supplied into the processing chamber 12 are adsorbed on the surface of the wafer W on the stage 13. Then, the valve 53c is closed.

In the first purge step, the valve 53a is opened, and the purge gas, of which the flow rate is controlled by the MFC 52a, is supplied into the plasma generation chamber 11 through the gas supply pipe 54a. The purge gas supplied into the plasma generation chamber 11 diffuses in the plasma generation chamber 11, and is supplied into the processing chamber 12 through the through holes in the separation unit 20 in a shower shape. The purge gas supplied into the processing chamber 12 purges the molecules of the precursor excessively adsorbed on the surface of the wafer W. Then, the valve 53a is closed.

In the reaction step, the valve 53b is opened, and the reaction gas, of which the flow rate is controlled by the MFC 52b, is supplied into the plasma generation chamber 11 through the gas supply pipe 54a. The reaction gas supplied into the plasma generation chamber 11 diffuses in the plasma generation chamber 11. Then, the first high-frequency power from the high-frequency power supply 32 is supplied into the plasma generation chamber 11 via the matcher 31 and the electrode 30, and the reaction gas in the plasma generation chamber 11 is converted into plasma. In addition, the second high-frequency power from the high-frequency power supply 203 is supplied into the plasma generation chamber 11 via the matcher 202 and the electrode plate 200, and the distribution of the plasma in the plasma generation chamber 11 is controlled.

The active species contained in the plasma are supplied into the processing chamber 12 through the through holes in the separation unit 20. The active species supplied into the processing chamber 12 react with the molecules of the precursor gas adsorbed on the wafer W. and forms a predetermined film so as to be laminated on the wafer W. Then, the valve 53b is closed. The ions contained in the plasma are absorbed by the electrode plate 200, the cooling plate 220, or the gas supply plate 230, and are hardly supplied to the processing chamber 12. This reduces ion damage to the wafer W.

In the second purge step, the valve 53a is opened, and the purge gas, of which the flow rate is controlled by the MFC 52a, is supplied into the plasma generation chamber 11 through the gas supply pipe 54a. The purge gas supplied into the plasma generation chamber 11 diffuses in the plasma generation chamber 11, and is supplied into the processing chamber 12 through the through holes in the separation unit 20 in a shower shape. The purge gas supplied into the processing chamber 12 purges reaction by-products and the like formed on the surface of the wafer W. Then, the valve 53a is closed.

The first embodiment has been described. As described above, the plasma processing apparatus 1 of the present embodiment includes a gas supply 50a, a high-frequency power supply 32, an electrode plate 200, and a cooling plate 220. The gas supply 50a supplies gas into the plasma generation chamber 11. The high-frequency power supply 32 converts the gas supplied into the plasma generation chamber 11 into plasma by supplying the first high-frequency power into the plasma generation chamber 11. The electrode plate 200 is a plate-shaped electrode plate 20X), which separates the plasma generation chamber 11 from the processing chamber 12 below the plasma generation chamber 11, and has a plurality of through holes 201 for guiding active species, contained in the plasma generated in the plasma generation chamber 11, to the processing chamber 12. The cooling plate 220 has the flow path 222 through which a fluid, of which the temperature is controlled, flows, and controls the temperature of the electrode plate 200 by heat exchange with the fluid. Thus, it is possible to suppress the temperature rise of the separation plate.

In the above-described embodiment, the electrode plate 200 is formed of a metal. In addition, the plasma processing apparatus 1 further includes a high-frequency power supply 203 configured to supply the second high-frequency power having a frequency different from that of the first high-frequency power to the electrode plate 200. The cooling plate 220 is in contact with the surface of the separation plate near the processing chamber 12 via the insulating plate 210. Thus, it is possible to suppress the temperature rise of the separation plate while insulating the electrode plate 200 and the cooling plate 220.

### Second Embodiment

In the first embodiment, the inside of the flow path 222 of the cooling plate 220 is a cavity. In contrast, the cooling plate 220 of the present embodiment differs from that in the first embodiment in that the flow path 222 is filled with a porous metal. The other parts of the plasma processing apparatus 1 other than the cooling plate 220 are the same as those of the plasma processing apparatus 1 according to the first embodiment, and detailed descriptions thereof will be omitted.

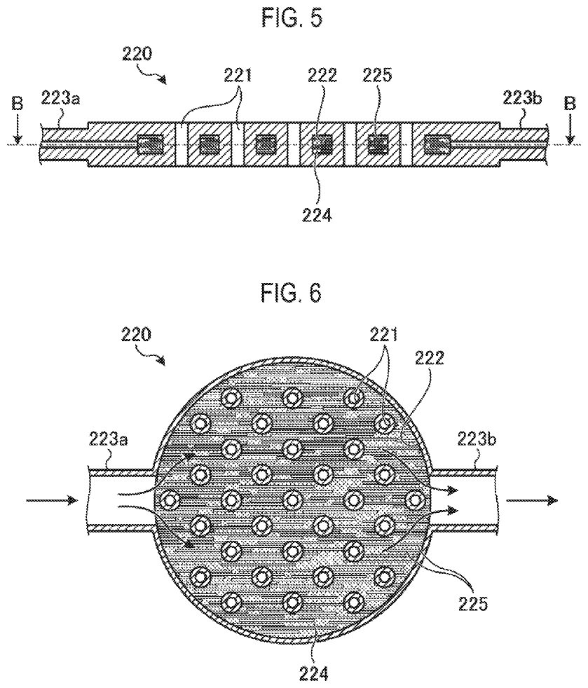

FIG. 5 is a cross-sectional view illustrating an exemplary cooling plate 220 in the second embodiment of the present disclosure. FIG. 6 is a cross-sectional view illustrating the exemplary cooling plate 220 in the second embodiment of the present disclosure, taken along line B-B in FIG. 5. The plan view of the cooling plate 220 in the present embodiment is the same as that in FIG. 2. A-A cross section of the cooling plate 220 of the present embodiment, which is identical to that in FIG. 2, corresponds to FIG. 5, and the B-B cross section of the cooling plate 220 exemplified in FIG. 5 corresponds to FIG. 6.

For example, as illustrated in FIGS. 5 and 6, a porous metal 224 having a large number of cavities 225 is arranged in the flow path 222. Each cavity 225 has an elongated shape extending in the direction from the pipe 223a to the pipe 223b. Each cavity 225 is connected to one or more other cavities 225. For that reason, the fluid that has flowed into the flow path 222 through the pipe 223a flows through the cavities 225 in the porous metal 224, and is returned to the temperature control device, such as a chiller, through the pipe 223b. When the fluid flows in the cavities 225, heat is exchanged between the fluid and the porous metal 224, and the heat of the porous metal 224 is transferred to the cooling plate 220. Thus, heat exchange between the fluid and the cooling plate 220 can be performed more efficiently.

The second embodiment has been described. As described above, in the plasma processing apparatus 1 of the present embodiment, the porous metal 224 is arranged in the flow path 222 in the cooling plate 220. Thus, heat exchange between the fluid and the cooling plate 220 can be performed more efficiently.

### Third Embodiment

In the first embodiment, since the flow of the fluid in the flow path 222 in the cooling plate 220 is delayed in a region far from the pipe 223a and the pipe 223b, the heat dissipation efficiency by the fluid may be reduced. In contrast, the present embodiment differs from the first embodiment in that a guide wall is provided in the flow path 222 in the cooling plate 220 such that the fluid flows through the entire flow path 222. The other parts of the plasma processing apparatus 1 other than the cooling plate 220 are the same as those of the plasma processing apparatus 1 according to the first embodiment, and detailed descriptions thereof will be omitted.

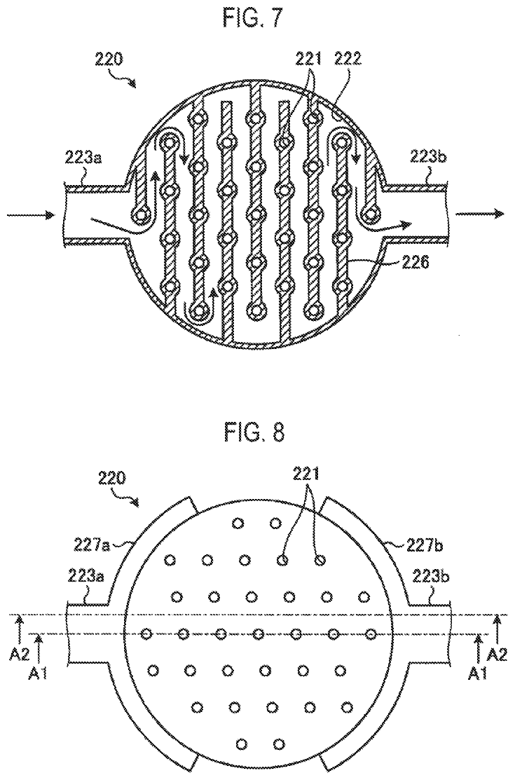

FIG. 7 is a cross-sectional view illustrating an exemplary cooling plate 220 in a third embodiment of the present disclosure. For example, as illustrated in FIG. 7, a guide wall 226 is provided in the flow path 222. The guide wall 226 regulates the flow path of the fluid flowing in the flow path 222 so as to flow through the entire flow path 222. This allows the fluid to flow through the entire flow path 222, for example, as indicated by the arrows in FIG. 7. This makes it possible to suppress a decrease in the heat dissipation efficiency by the fluid, and thus efficiently cool the separation unit 20.

### Fourth Embodiment

In the third embodiment, by providing the guide wall 226 in the flow path 222, the fluid flows in a direction intersecting the direction from the pipe 223a to the pipe 223b. In contrast, the present embodiment differs from the third embodiment in that a plurality of flow passages is formed in the flow path 222 in the direction from the pipe 223a to the pipe 223b. The other parts of the plasma processing apparatus 1 other than the cooling plate 220 are the same as those of the plasma processing apparatus 1 according to the third embodiment, and detailed descriptions thereof will be omitted.

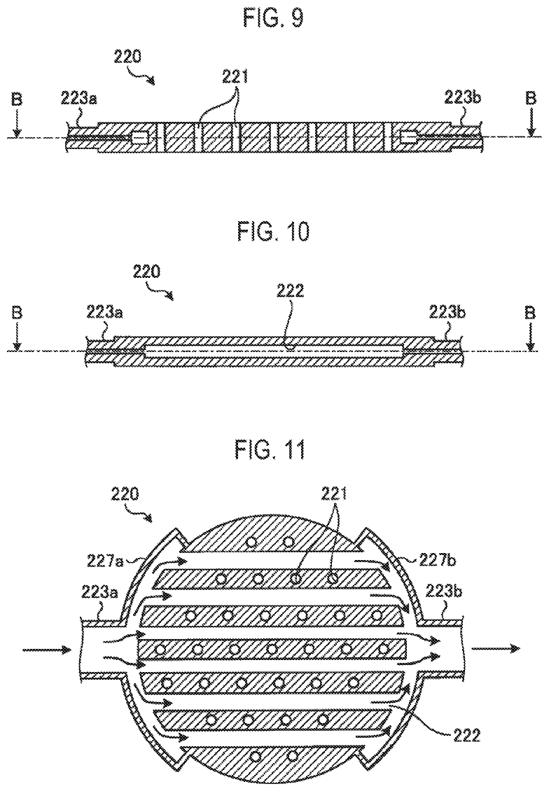

FIG. 8 is a plan view illustrating an exemplary cooling plate 220 in a fourth embodiment of the present disclosure. FIG. 9 is a cross-sectional view illustrating the exemplary cooling plate 220 in the fourth embodiment of the present disclosure, taken along line A1-A1. FIG. 10 is a cross-sectional view illustrating the exemplary cooling plate 220 in the fourth embodiment of the present disclosure, taken along line A2-A2. FIG. 11 is a cross-sectional view illustrating the exemplar) cooling plate 220 in the fourth embodiment of the present disclosure, taken along line B-B. The A1-A1 cross section of the cooling plate 220 exemplified in FIG. 8 corresponds to FIG. 9, the A2-A2 cross section of the cooling plate 220 exemplified in FIG. 8 corresponds to FIG. 10, and the B-B cross section of the cooling plate 220 exemplified in FIGS. 9 and 10 corresponds to FIG. 11.

For example, as illustrated in FIG. 11, a plurality of flow paths 222 are formed in the cooling plate 220 in a direction from the pipe 223a to the pipe 223b. The fluid supplied from the pipe 223a flows into each flow path 222 through a branch portion 227a. Then, the fluid that has flowed through each flow path 222 flows to the pipe 223b through a collecting portion 227b, and is returned to a temperature control device such as a chiller. Each flow path 222 in the present embodiment is formed in a direction from the pipe 223a to the pipe 223b. For that reason, it is possible to reduce the pressure loss of the fluid when flowing in the flow path 222, and thus reduce the load on the pump of the temperature control device such as a chiller.

### Fifth Embodiment

In the fourth embodiment, each flow path 222 in the cooling plate 220 is a cavity. In contrast, the cooling plate 220 of the present embodiment differs from that in the fourth embodiment in that the flow path 222 is filled with a porous metal. The other parts of the plasma processing apparatus 1 other than the cooling plate 220 are the same as those of the plasma processing apparatus 1 according to the fourth embodiment, and detailed descriptions thereof will be omitted.

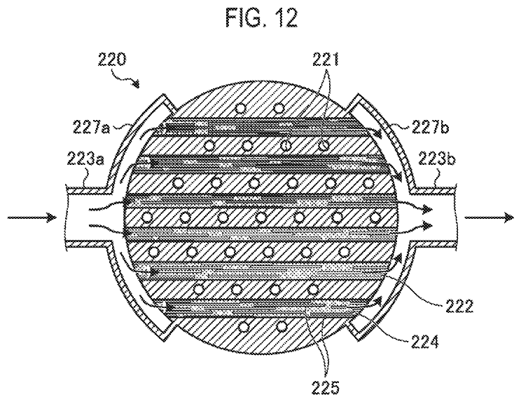

FIG. 12 is a cross-sectional view illustrating an exemplary cooling plate 220 in a fifth embodiment of the present disclosure. For example, as illustrated in FIG. 12, a porous metal 224 having a large number of cavities 225 are arranged in each flow path 222. Each cavity 225 has an elongated shape extending in the direction from the pipe 223a to the pipe 223b. Each cavity 225 is connected to one or more other cavities 225. For that reason, the fluid supplied through the pipe 223a flows through the cavities 225 in the porous metal 224 disposed in each of the flow paths 222 via a branch portion 227a, and is returned to a temperature control device such as a chiller through the collecting portion 227b and the pipe 223b. By arranging the porous metal 224 in each of the flow paths 222, heat exchange between the fluid and the cooling plate 220 can be performed more efficiently.

### Sixth Embodiment

The separation unit 20 in the first embodiment includes an electrode plate 200, an insulating plate 210, a cooling plate 220, and a gas supply plate 230. In contrast, the separation unit 20 of the present embodiment differs from that in the first embodiment in that it includes the cooling plate 220 but does not include the electrode plate 200, the insulating plate 210, and the gas supply plate 230. The following description focuses on the differences from the first embodiment.

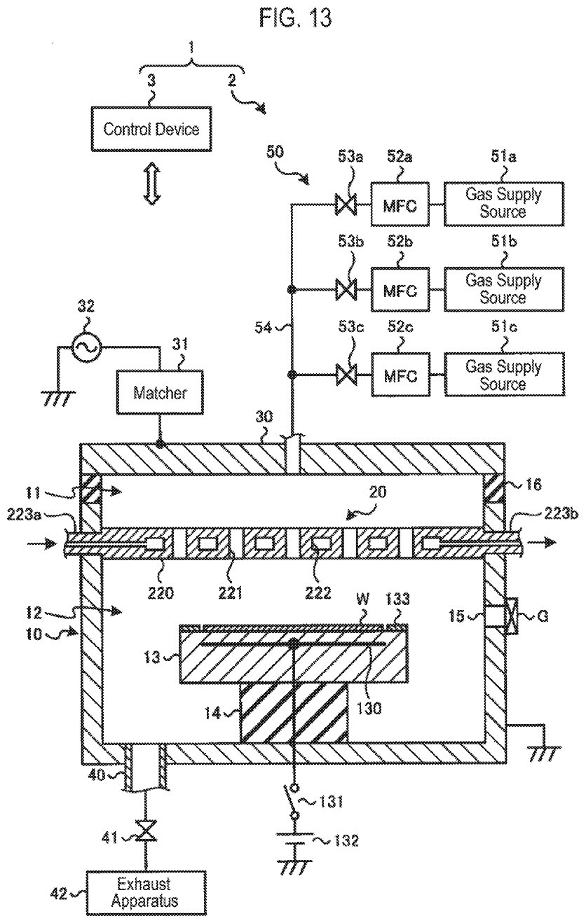

FIG. 13 is a schematic cross-sectional view illustrating an exemplary plasma processing apparatus 1 in a sixth embodiment of the present disclosure. In the present embodiment, the separation unit 20 has a cooling plate 220. The cooling plate 220 is grounded via the processing container 10 and functions as a lower electrode with respect to the electrode 30. The space in the plasma generation chamber 11 and the space in the processing chamber 12 are connected via through holes 221 in the cooling plate 220.

A gas supply 50 is connected to the electrode 30 via a gas supply pipe 54. The gas supply 50 includes gas supply sources 51a to 51c, MFCs 52a to 52c, and valves 53a to 53c. The flow rate of a precursor gas supplied from the gas supply source 51c is controlled by the MFC 52c, and is supplied into the plasma generation chamber 11 through the valve 53c and the gas supply pipe 54. The precursor gas supplied into the plasma generation chamber 11 diffuses in the plasma generation chamber 11 and is supplied to the processing chamber 12 through the through holes 221 in the cooling plate 220 in a shower shape.

Ions contained in the plasma generated in the plasma generation chamber 11 are absorbed by the cooling plate 220 and are hardly supplied to the processing chamber 12. For that reason, the present embodiment also reduces ion damage to a wafer W.

In the present embodiment, the cooling plate 220 has both the function of a separation plate for separating the plasma generation chamber 11 and the processing chamber 12 and the function of a temperature controller for controlling the temperature of the separation plate through heat exchange with a fluid since the cooling plate 220 has therein a flow path through which the fluid flows in a temperature-controlled manner. That is, in the present embodiment, the temperature controller and the separation plate are integrally configured as the cooling plate 220.

### Seventh Embodiment

The cooling plate 220 in the sixth embodiment is grounded via the processing container 10. In contrast, the present embodiment differs from the sixth embodiment in that high-frequency power is supplied to the cooling plate 220. The following description focuses on the differences from the sixth embodiment.

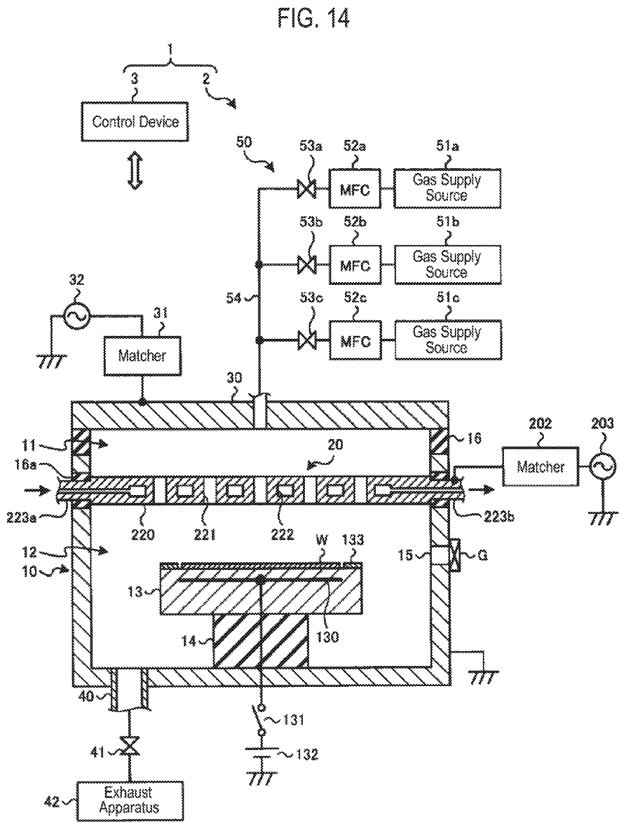

FIG. 14 is a schematic cross-sectional view illustrating an exemplary plasma processing apparatus 1 in a seventh embodiment of the present disclosure. In the present embodiment, the separation unit 20 has a cooling plate 220. The space in the plasma generation chamber 11 and the space in the processing chamber 12 are connected via through holes 221 in the cooling plate 220. The cooling plate 220 is supported by the processing container 10 via an insulating member 16a. A high-frequency power supply 203 is electrically connected to the cooling plate 220 via a matcher 202. The high-frequency power supply 203 supplies the second high-frequency power to the cooling plate 220 via the matcher 202. This makes it possible to control the distribution of plasma in the plasma generation chamber 11, the density of plasma in the plasma generation chamber 11, the amount of active species passing through the through holes 221 in the cooling plate 220, and the like, while reducing ion damage to the wafer W.

In the first embodiment, the cooling plate 220 may also be supported by the processing container 10 via the insulating member 16a, and the high-frequency power supply 203 may be connected to the cooling plate 220 via the matcher 202. In this case, the electrode plate 200 is not provided. The insulating plate 210 is disposed preferably between the cooling plate 220 and the gas supply plate 230.

### [Others]

The technology disclosed herein is not limited to the embodiments described above, and various modifications are possible within the scope of the gist of the present disclosure.

For example, in the first to fifth embodiments described above, the insulating plate 210 is interposed between the electrode plate 200 and the cooling plate 220, but the disclosed technology is not limited thereto. Alternatively, the electrode plate 200 and the cooling plate 220 may be in direct contact, and the insulating plate 210 may be interposed between the cooling plate 220 and the gas supply plate 230. In this case, the lower surface of the electrode plate 200 and the upper surface of the cooling plate 220 are preferably joined through welding or the like. This makes it possible to perform heat exchange between the electrode plate 200 and the cooling plate 220 more efficiently.

In addition, in each of the above embodiments, the plasma processing apparatus 1 for forming a predetermined film on a wafer W through PEALD method has been described as an example, but the technology disclosed herein is not limited thereto. The technology disclosed herein is applicable to an apparatus that performs film formation by plasma chemical vapor deposition (CVD) method as long as the apparatus performs film formation using plasma. In addition, the technology disclosed herein is applicable to an etching apparatus, a cleaning apparatus, and the like as long as the apparatus performs processing using plasma.

In each of the embodiments described above, capacitively coupled plasma (CCP) is used as an example of a plasma source, but the technology disclosed herein is not limited thereto. As the plasma source, for example, inductively coupled plasma (ICP), microwave-excited surface wave plasma (SWP), electron cyclotron resonance plasma (ECP), or helicon wave-excited plasma (HWP) may be used.

According to various aspects and embodiments of the present disclosure, it is possible to suppress temperature rise of the separation plate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus comprising:
a gas supply configured to supply a gas into a plasma generation chamber;
a first power supply configured to convert the gas supplied into the plasma generation chamber into plasma by supplying a first high-frequency power into the plasma generation chamber;
a separation plate having a plate-shape and configured to separate the plasma generation chamber and a processing chamber below the plasma generation chamber, the separation plate having a plurality of through holes so as to guide active species contained in the plasma generated in the plasma generation chamber to the processing chamber; and
a temperature controller having a flow path through which a fluid flows in a temperature-controlled manner, the temperature controller being configured to control a temperature of the separation plate through heat exchange with the fluid.

2. The plasma processing apparatus of claim 1, further comprising a second power supply configured to supply, to the separation plate, a second high-frequency power different from the first high-frequency power in frequency,
wherein the separation plate is formed of a metal, and the temperature controller is in contact with a surface of the separation plate near the processing chamber via an insulating plate.

3. The plasma processing apparatus of claim 1, wherein the temperature controller is integrally formed with the separation plate.

4. The plasma processing apparatus of claim 1, wherein a porous metal is arranged in the flow path of the temperature controller.

5. The plasma processing apparatus of claim 2, wherein a porous metal is arranged in the flow path of the temperature controller.

6. The plasma processing apparatus of claim 3, wherein a porous metal is arranged in the flow path of the temperature controller.
